(19) United States
(12) Patent Application Publication
(10) Pub. No.: US 2007/0134563 A1
(43) Pub. Date: Jun. 14, 2007

(54) Photomask and method of manufacturing semiconductor device

(76) Inventors: Kazuya Fukuhara, Tokyo (JP); Masamitsu Itoh, Yokohama-shi (JP); Takashi Sato, Fujisawa-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/600,783

(22) Filed: Nov. 17, 2006

(30) Foreign Application Priority Data
Nov. 18, 2005 (JP) 2005-334849

(51) Int. Cl. G03C 5/00; G03F 1/00

(52) U.S. Cl. 430/5; 430/322; 430/323; 430/394

(57) ABSTRACT

A photomask is disclosed, which includes a substrate transparent to irradiation light, a low density diffraction area having a plurality of low-density arranged light reducing portions which are arranged at a low density on the transparent substrate at a period more than twice the wavelength of the irradiation light, and a high density diffraction area having a plurality of high-density arranged light reducing portions which are arranged at a high density on the transparent substrate at a period less than twice the wavelength of the irradiation light and have different optical characteristics from the low-density arranged light reducing portions.

### CROSS-REFERENCE TO RELATED APPLICATIONS

This application is based upon and claims the benefit of priority from prior Japanese Patent Application No. 2005-334849, filed Nov. 18, 2005, the entire contents of which are incorporated herein by reference.

### BACKGROUND OF THE INVENTION

1. Field of the Invention

The present invention relates to a lithography technique and, more particularly, to a photomask and a method of manufacturing a semiconductor device.

2. Description of the Related Art

Increase in accuracy of a lithography process is an important factor in advancing fineness of a semiconductor device pattern. In recent years, a phase shift exposure method, an oblique incidence method, and a multipole illumination method based on a polarized illumination method have been tried to be introduced in an exposure process in order to advance the fineness of a semiconductor device (refer to, e.g., Japanese Patent No. 3246615). However, when the period of the pattern formed on a photomask becomes less than twice the wavelength of light irradiated onto the photomask, contrast of a projection image of the pattern is not sufficiently increased if the phase shift exposure method is used. Thus, when manufacturing a semiconductor memory device in which a memory cell region with a finer pattern period and a peripheral circuit region with a pattern period greater than that of the memory cell region are mixed, a large manufacturing error occurs in the pattern of the memory cell region during a lithography process while the pattern of the peripheral circuit region is formed satisfactorily.

### BRIEF SUMMARY OF THE INVENTION

According to an aspect of the present invention, there is provided a photomask comprising:

a substrate transparent to irradiation light;

a low density diffraction area having a plurality of low-density arranged light reducing portions which are arranged at a low density on the transparent substrate at a period more than twice the wavelength of the irradiation light; and

a high density diffraction area having a plurality of high-density arranged light reducing portions which are arranged at a high density on the transparent substrate at a period less than twice the wavelength of the irradiation light and have different optical characteristics from the low-density arranged light reducing portions.

According to another aspect of the present invention, there is provided a method of manufacturing a semiconductor device, comprising:

emitting irradiation light;

condensing the emitted irradiation light;

entering the condensed irradiation light obliquely to a low density diffraction area having a plurality of low-density arranged light reducing portions which are arranged at a period more than twice a wavelength of the irradiation light and a high density diffraction area having a plurality of high-density arranged light reducing portions which are arranged at a period less than twice the wavelength and having different optical characteristics from the low-density arranged light reducing portions;

forming projection images of the high density diffraction area and low density diffraction area on a resist film for projection coated on a wafer by the oblique entering of the irradiation light; and

developing the resist film for projection to form a resist pattern corresponding to the projection images on the wafer.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic top view of a photomask according to an embodiment of the present invention;

FIG. 2 is a cross sectional view of the photomask according to the embodiment of the present invention, taken along II-II line of FIG. 1, as viewed in the direction of the arrow in FIG. 1;

FIG. 3 is an enlarged top view of a high density diffraction area of the photomask according to the embodiment of the present invention;

FIG. 4 is an enlarged top view of a low density diffraction area of the photomask according to the embodiment of the present invention;

FIG. 5 is a view schematically showing a configuration of an exposure unit according to the embodiment of the present invention;

FIG. 6 is a top view of a first example of a polarizer in the exposure unit according to the embodiment of the present invention;

FIG. 7 is a top view of a second example of the polarizer in the exposure unit according to the embodiment of the present invention;

FIG. 8 is a view schematically showing a relationship between the photomask and irradiation light in the embodiment of the present invention;

FIG. 9 is a cross sectional view of a structure of the photomask according to the embodiment of the present invention in a manufacturing process;

FIG. 10 is a cross sectional view of the structure of the photomask according to the embodiment of the present invention in a manufacturing process following the process of FIG. 9;

FIG. 11 is a cross sectional view of the structure of the photomask according to the embodiment of the present invention in a manufacturing process following the process of FIG. 10;

FIG. 12 is a cross sectional view of the structure of the photomask according to the embodiment of the present invention in a manufacturing process following the process of FIG. 11;

FIG. 13 is a cross sectional view of the structure of the photomask according to the embodiment of the present invention in a manufacturing process following the process of FIG. 12;

FIG. 14 is a cross sectional view of the structure of the photomask according to the embodiment of the present invention in a manufacturing process following the process of FIG. 13;

FIG. 15 is a cross sectional view of the structure of the photomask according to the embodiment of the present invention in a manufacturing process following the process of FIG. 14;

FIG. 16 is a cross sectional view of the structure of the photomask according to the embodiment of the present invention in a manufacturing process following the process of FIG. 15;

FIG. 17 is a flowchart showing a method of manufacturing a semiconductor device according to an embodiment of the present invention;

FIG. 18 is a cross sectional view of a photomask according to a first modification of the embodiment shown in FIGS. 2-4 of the present invention;

FIG. 19 is a cross sectional view of a structure of the photomask according to the first modification of the embodiment in a manufacturing process;

FIG. 20 is a cross sectional view of the structure of the photomask according to the first modification of the embodiment in a manufacturing process following the process of FIG. 19;

FIG. 21 is a cross sectional view of the structure of the photomask according to the first modification of the embodiment in a manufacturing process following the process of FIG. 20;

FIG. 22 is a cross sectional view of the structure of the photomask according to the first modification of the embodiment in a manufacturing process following the process of FIG. 21;

FIG. 23 is a cross sectional view of the structure of the photomask according to the first modification of the embodiment in a manufacturing process following the process of FIG. 22;

FIG. 24 is a cross sectional view of the structure of the photomask according to the first modification of the embodiment in a manufacturing process following the process of FIG. 23;

FIG. 25 is a cross sectional view of a photomask according to a second modification of the embodiment shown in FIGS. 2-4 of the present invention;

FIG. 26 is a cross sectional view of a structure of the photomask according to the second modification of the embodiment in a manufacturing process;

FIG. 27 is a cross sectional view of the structure of the photomask according to the second modification of the embodiment in a manufacturing process following the process of FIG. 26;

FIG. 28 is a cross sectional view of the structure of the photomask according to the second modification of the embodiment in a manufacturing process following the process of FIG. 27;

FIG. 29 is a cross sectional view of the structure of the photomask according to the second modification of the embodiment in a manufacturing process following the process of FIG. 28; and

FIG. 30 is a cross sectional view of the structure of the photomask according to the second modification of the embodiment in a manufacturing process following the process of FIG. 29.

### DETAILED DESCRIPTION OF THE INVENTION

Embodiments of the present invention will be described below with reference to the accompanying drawings. In the following description, the same or corresponding reference numerals denote the same or corresponding parts throughout the drawings. The following embodiments merely exemplify a device or method for embodying the technical concept of the present invention, and does not limit, e.g., arrangement of constituent elements to that described below. Various modifications may be added to the technical concept of the present invention within the scope of claims.

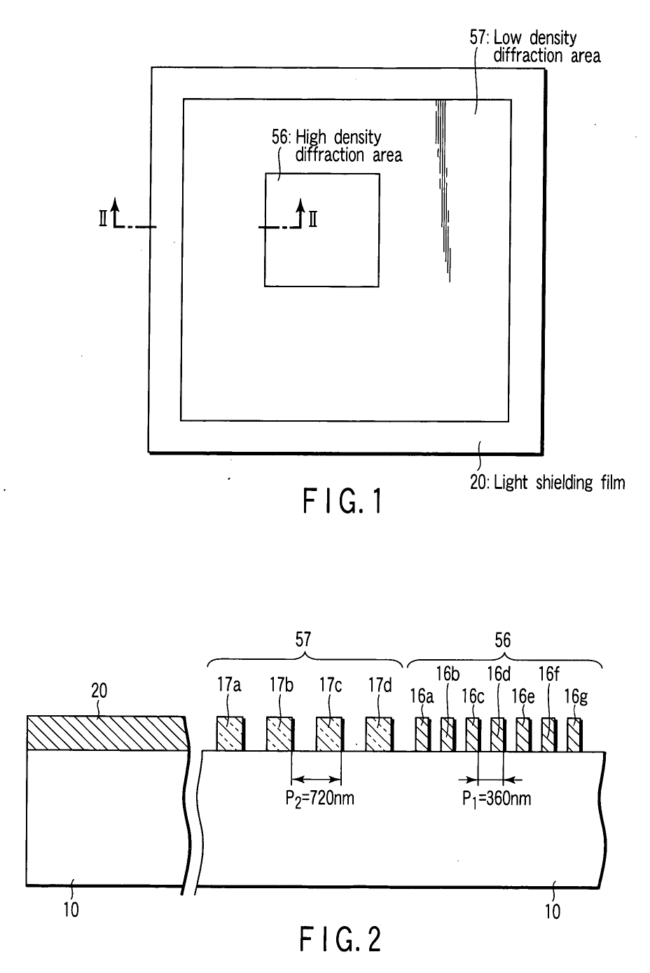

As shown in FIGS. 1 and 2, a photomask according to an embodiment of the present invention has a substrate 10 which receives irradiation light and is transparent with respect to the irradiation light, a low density diffraction area 57 having a plurality of low-density arranged light reducing portions 17a, 17b, 17c, and 17d which are arranged in a low density on the substrate 10 at a period P₂ more than twice the wavelength of irradiation light, and a high density diffraction area 56 having a plurality of high-density arranged light reducing portions 16a, 16b, 16c, 16d, 16e, 16f, and 16g which are surrounded by the low density diffraction area 57, arranged at a high density on the substrate 10 at a period P₁ less than twice the wavelength of irradiation light, and have a different optical characteristic from that of the low-density arranged light reducing portions 17a to 17d. An optical constant of the high-density arranged light reducing portions 16a to 16g is defined such that the light amount ratio, which is a ratio of the light amount of primary diffraction light relative to that of zero-order diffraction light in the high density diffraction area 56, is set to fall within a range of 0.8 to 1.2, preferably become 1. Silica glass (SiO₂) or the like can be used as a material of the substrate 10. A light shielding film 20 made of chromium (Cr) or the like is so formed on the substrate 10 as to surround the low density diffraction area 57.

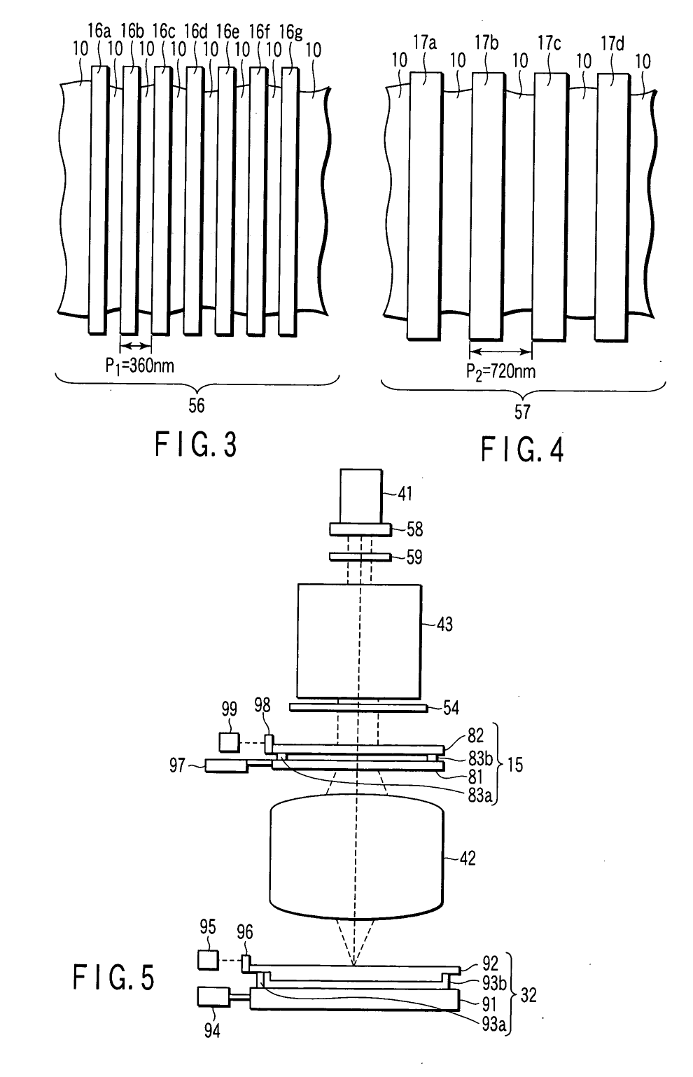

A pattern corresponding to a memory cell region or the like of a semiconductor device is formed on the high density diffraction area 56. As shown in an enlarged top view of FIG. 3, the high density diffraction area 56 has the high-density arranged light reducing portions 16a, 16b, 16c, 16d, 16e, 16f, and 16g which are arranged at the period P₁ less than twice the wavelength λ of light to be irradiated onto the substrate 10. Light shielding metal such as Cr can be used as a material of the high-density arranged light reducing portions 16a to 16g. In the case where the photomask is formed on the assumption that it is irradiated by an argon fluoride (ArF) laser having a wavelength of 193 nm or the like, the high-density arranged light reducing portions 16a to 16g are arranged on the substrate 10 at a period of, e.g., 360 nm.

A pattern corresponding to a peripheral circuit or the like of a semiconductor device is formed on the low density diffraction area 57. As shown in an enlarged top view of FIG. 4, the low density diffraction area 57 has the low-density arranged light reducing portions 17a, 17b, 17c, and 17d which are arranged at the period P₂ more than twice the wavelength λ of light to be irradiated onto the substrate 10. A semitransparent transition element compound such as molybdenum silicide (MoSi) can be used as a material of the low-density arranged light reducing portions 17a to 17d. The transmittance of the low-density arranged light reducing portions 17a to 17d is, e.g., 2 to 20%. The low-density arranged light reducing portions 17a to 17d have a film thickness such that a transmitted light of the irradiation light irradiated on the transparent substrate 10, which is directly emitted from the transparent substrate 10, is shifted by 180° in phase from a transmitted light of the irradiation light irradiated on the transparent substrate 10, which is passed through the transparent substrate 10 and the low-density arranged light reducing portions 17a to 17d and emitted from the low-density arranged light reducing portions 17a to 17d. In the case where the photomask is formed on the assumption that it is irradiated by an ArF laser or the like, the low-density arranged light reducing portions 17a to 17d are arranged on the substrate 10 at a period of, e.g., 720 nm. The materials of the high-density arranged light reducing portions 16a to 16g and low-density arranged light reducing portions 17a to 17d are selected so that the extinction coefficient (i.e., an optical characteristic with respect to irradiation light) of the high-density arranged light reducing portions 16a to 16g becomes larger than the extinction coefficient of the low-density arranged light reducing portions 17a to 17d. Extinction coefficient is a coefficient concerning light absorption amount.

The photomask shown in FIGS. 1 to 4 is disposed in an exposure unit shown in FIG. 5. The exposure unit includes an irradiation light source 41 which emits irradiation light such as an ArF laser, an aperture diaphragm holder 58 disposed on the light-emission side of the irradiation light source 41, a polarizer 59 which converts irradiation light emitted from the irradiation light source 41 into polarized light, a light condensation unit 43 which condenses light, a slit holder 54 disposed on the light-emission side of the light condensation unit 43, a reticle stage 15 disposed below the slit holder 54, a projection optical unit 42 disposed below the reticle stage 15, and a wafer stage 32 disposed below the projection optical unit 42.

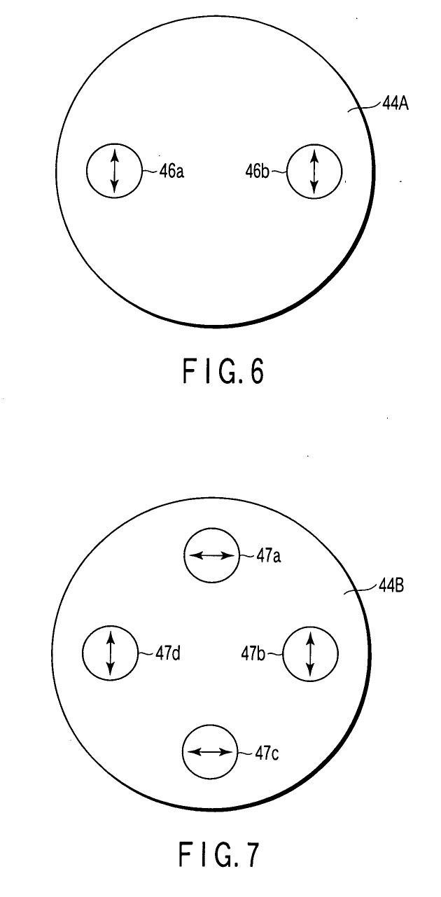

The polarizer 59 has, as shown in FIG. 6, a light shielding plate 44A and two circular polarization windows 46a and 46b formed in the light shielding plate 44A. Polarization directions of the irradiation light passing through the polarization window 46a and irradiation light passing through the polarization window 46b are in parallel to each other, with the light axis being therebetween, as denoted by the arrows of FIG. 6. Alternatively, the polarizer 59 has, as shown in FIG. 7, a light-shielding plate 44B and four circular polarization windows 47a, 47b, 47c, and 47d formed in the light shielding plate 44B. Polarization directions of the irradiation light passing through the polarization window 47a and irradiation light passing through the polarization window 47b are in parallel to each other, with the light axis being therebetween, as denoted by the arrows of FIG. 7. Similarly, polarization directions of the irradiation light passing through the polarization window 47c and irradiation light passing through the polarization window 47d are in parallel to each other, with the light axis being therebetween, as denoted by the arrows of FIG. 7. The direction in which the irradiation lights passing through the polarization windows 47a and 47b are in parallel to each other and the direction in which the irradiation lights passing through the polarization windows 47c and 47d are in parallel to each other cross to each other at right angles. As described above, multipole illumination such as dipole illumination and quadrupole illumination is set in accordance with the configuration of the polarizer 59.

The photomask is disposed on the reticle stage 15 shown in FIG. 5. The reticle stage 15 includes a reticle XY stage 81, movable shafts 83a and 83b for a reticle, disposed on the XY stage 81, and a Z inclinable stage 82 for the reticle, connected to the XY stage 81 through the movable shafts 83a and 83b. A reticle stage drive unit 97 is connected to the reticle stage 15. The reticle stage drive unit 97 drives the XY stage 81 in the horizontal direction and movable shafts 83a and 83b in the vertical direction. Thereby, the position of the Z inclinable stage 82 in the horizontal direction is controlled by the XY stage 81. At the same time, the Z inclinable stage 82 can be inclined by the movable shafts 83a and 83b relative to the horizontal plane. A reticle moving mirror 98 is disposed at the end portion of the Z inclinable stage 82. The position of the Z inclinable stage 82 is measured by a reticle laser interferometer 99 disposed opposite to the moving mirror 98.

The numerical aperture (NA) of the projection optical system 42 is, e.g., 1.3, and the projection magnification thereof is ¼. A wafer on which a resist film for projection has been coated is disposed on the wafer stage 32. A pattern formed on the photomask is projected on the resist film. The wafer stage 32 includes a wafer XY stage 91, movable shafts 93a and 93b for a wafer, disposed on the wafer XY stage 91, and a Z inclinable stage 92 for the wafer, connected to the wafer XY stage 91 through the movable shafts 93a and 93b. A wafer stage drive section 94 is connected to the wafer stage 32. The wafer stage drive section 94 drives the XY stage 91 in the horizontal direction and movable shafts 93a and 93b in the vertical direction. Thus, the position of the Z inclinable stage 92 in the horizontal direction is controlled by the XY stage 91. At the same time, the Z inclinable stage 92 can be inclined by the movable shafts 93a and 93b relative to the horizontal plane. A wafer moving mirror 96 is disposed at the end portion of the Z inclinable stage 92. The position of the Z inclinable stage 92 is measured by a wafer laser interferometer 95 disposed opposite to the moving mirror 96.

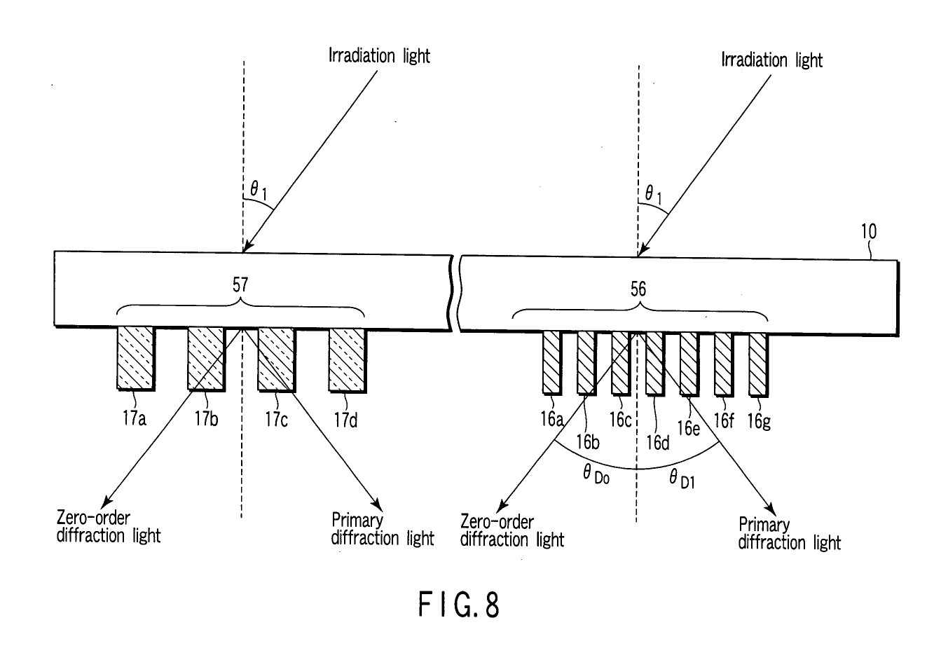

As shown in FIG. 8, when irradiation light enters the substrate 10 at an incident angle θI, zero-order diffraction light and primary diffraction light are generated in both the high density diffraction area 56 and low density diffraction area 57. The high density diffraction area 56 is made of Cr, which has light shielding characteristics, so that the extinction coefficient thereof is larger than in the case where the high density diffraction area 56 is made of MoSi. Therefore, the light amount ratio of the primary diffraction light relative to the zero-order diffraction light in the high density diffraction area 56 falls within a range of 0.8 to 1.2, preferably become 1. When the focusing optical system 43 is set such that the incident angle θI satisfies the following equation (1), output angle θD0 of the zero-order diffraction light and output angle θD1 of the primary diffraction light becomes equal to each other, with the result that a projection image of the pattern formed on the photomask is focused onto the resist film for projection with high accuracy.
θI=sin−1(λ/2P₁) (1)

In a conventional photomask, all the light reducing portions disposed on a transparent substrate are made of the same material irrespective of the period at which they are arranged. However, in the case where all the light reducing portions are made of MoSi, if the period at which the light reducing portions are arranged becomes less than twice the wavelength λ of irradiation light, the contrast of a projection image may become smaller than in the case where they are made of Cr. This is because that when the period at which the light reducing portions made of MoSi are arranged becomes equal or less than the wavelength λ of irradiation light, the light amount ratio of the primary diffraction light relative to the zero-order diffraction light moves away from 1, adversely affecting the image focusing.

On the other hand, in the photomask according to the embodiment shown in FIGS. 1 to 4, the high-density arranged light reducing portions 16a to 16g which are arranged at a period less than twice the wavelength λ of irradiation light are made of Cr having light shielding characteristics. Therefore, in the high-density arranged light reducing portions 16a to 16g, the light amount ratio of the primary diffraction light relative to the zero-order diffraction light falls within a range of 0.8 to 1.2, preferably becomes 1, so that the lithography tolerance with respect to focus depth or the like increases as compared to the case where the high-density arranged light reducing portions 16a to 16g are made of MoSi. As a result, the contrast of a projection image of the high-density arranged light reducing portions 16a to 16g which are arranged at a period less than twice the wavelength λ of irradiation light increases as compared to the case where all the light reducing portions are made of MoSi.

In the photomask according to the embodiment, the low-density arranged light reducing portions 17a to 17d which are arranged at a period more than twice the wavelength λ of irradiation light are made of MoSi. Further, the low-density arranged light reducing portions 17a to 17d have a film thickness such that a transmitted light of the irradiation light irradiated on the transparent substrate 10, which is directly emitted from the transparent substrate 10, is shifted by 180° in phase from a transmitted light of the irradiation light irradiated on the transparent substrate 10, which is passed through the transparent substrate 10 and the low-density light arranged reducing portions 17a to 17d and emitted from the low-density arranged light reducing portions 17a to 17d. When the arrangement period is set to more than twice the wavelength λ of irradiation light, the light amount ratio of the primary diffraction light relative to the zero-order diffraction light in the low density diffraction area 57 falls within a range of 0.8 to 1.2, preferably becomes 1 even if the low-density arranged light reducing portions 17a to 17d are made of MoSi. Further, forming the low density diffraction area 57 using MoSi achieves an attenuated phase shift pattern to increase the contrast of a projection image, thus increasing lithography margin. As a result, the contrast of a projection image of the low-density arranged light reducing portions 17a to 17d which are arranged at a period more than twice the wavelength λ of irradiation light increases as compared to the case where all the light reducing portions are made of Cr.

As described above, when the optical constant such as extinction coefficient or the like of the high-density arranged light reducing portions 16a to 16g and the optical constant of the low-density arranged light reducing portions 17a to 17d are made different from each other, it is possible to approximate the light amount ratio of the primary diffraction light relative to the zero-order diffraction light to 1 both in the high density diffraction area 56 and low density diffraction area 57 by use of the photomask according to the embodiment. As a result, a semiconductor device can be manufactured with high accuracy.

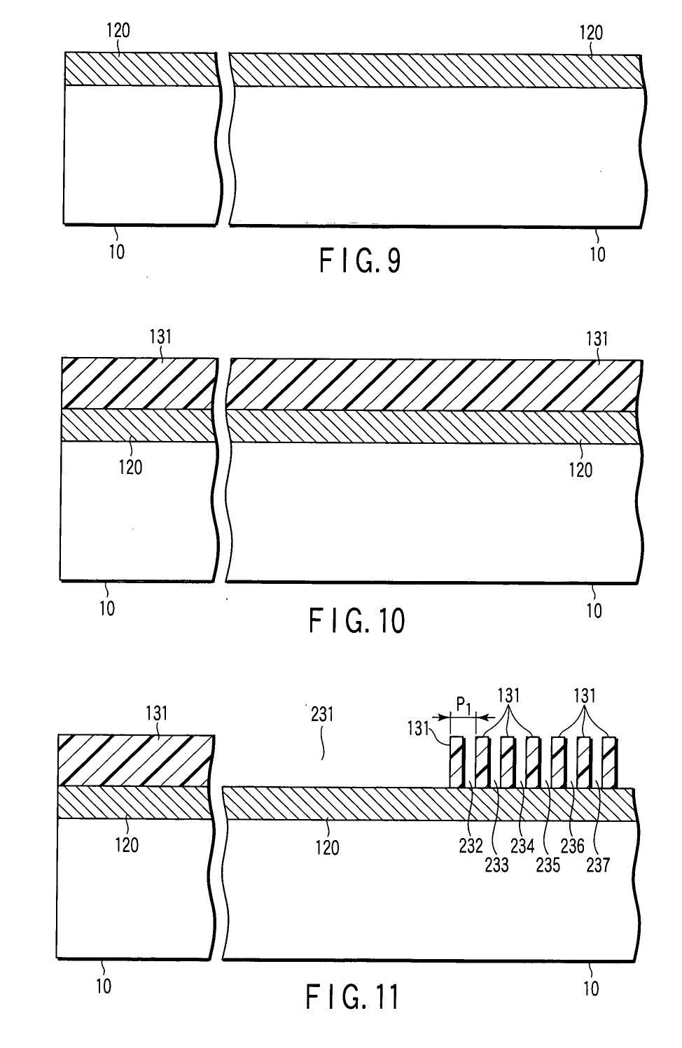

A method of manufacturing the photomask according to the embodiment will be described below with reference to FIGS. 9 to 16.

(a) The substrate 10 made of SiO₂ is prepared. Cr or the like is deposited on the substrate 10 to form a first deposition film 120 on the substrate 10, as shown in FIG. 9, by using vacuum deposition or the like. Then, a first resist film 131 is coated on the first deposition film 120, as shown in FIG. 10, by using spin coating or the like. After that, lithography is carried out to form a plurality of apertures 231, 232, 233, 234, 235, 236, and 237 in the first resist film 131, as shown in FIG. 11. The apertures 231 to 237 are arranged at a period P₁ less than twice the wavelength λ of light to be irradiated onto a photomask after manufactured.

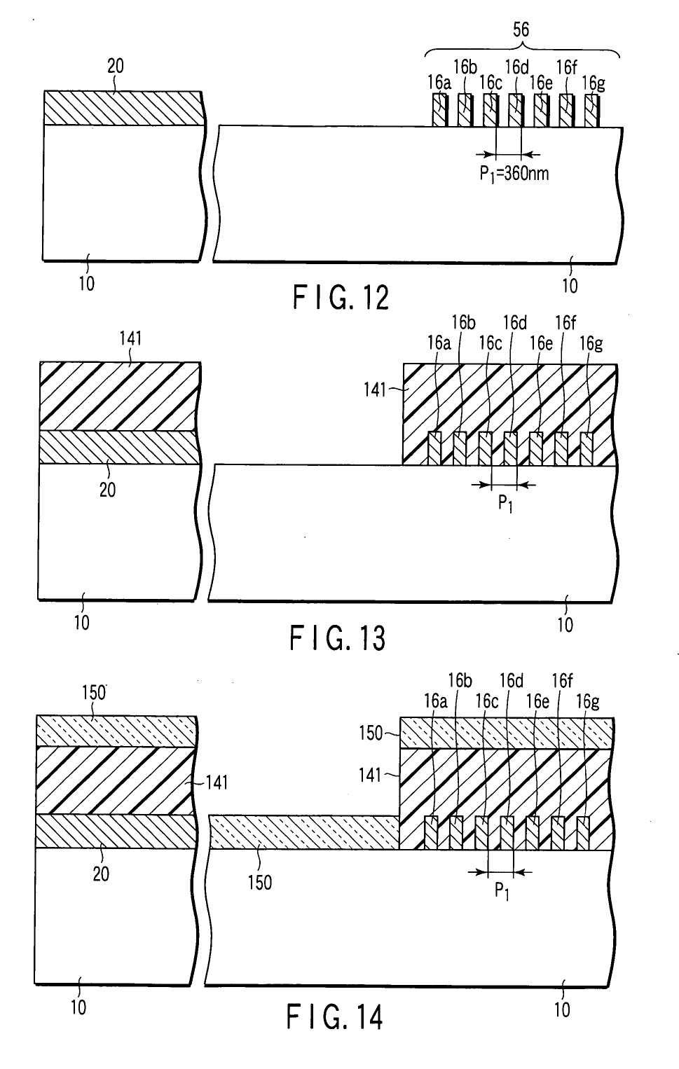

(b) Anisotropic etching is carried out to remove the part of the first deposition film 120 that is exposed through the apertures 231 to 237. After that, ashing is carried out to remove the first resist film 131 to form the light shielding film 20 made of Cr and high density diffraction area 56 having a plurality of high-density arranged light reducing portions 16a to 16g made of Cr or the like on the substrate 10, as shown in FIG. 12. Then, as shown in FIG. 13, a second resist film 141 is coated on the light shielding film 20 and high-density arranged light reducing portions 16a to 16g. After that, sputtering or the like is carried out to deposit MoSi or the like on the exposed surfaces of the second resist film 141 and substrate 10 to form a semitransparent film 150 on the entire surface of the substrate 10, as shown in FIG. 14. The semitransparent film 150 has a film thickness such that a transmitted light of the irradiation light irradiated on the transparent substrate 10, which is directly emitted from the transparent substrate 10, is shifted by 180° in phase from a transmitted light of the irradiation light irradiated on the transparent substrate 10, which is passed through the transparent substrate 10 and the semitransparent film 150 and emitted from the semitransparent film 150.

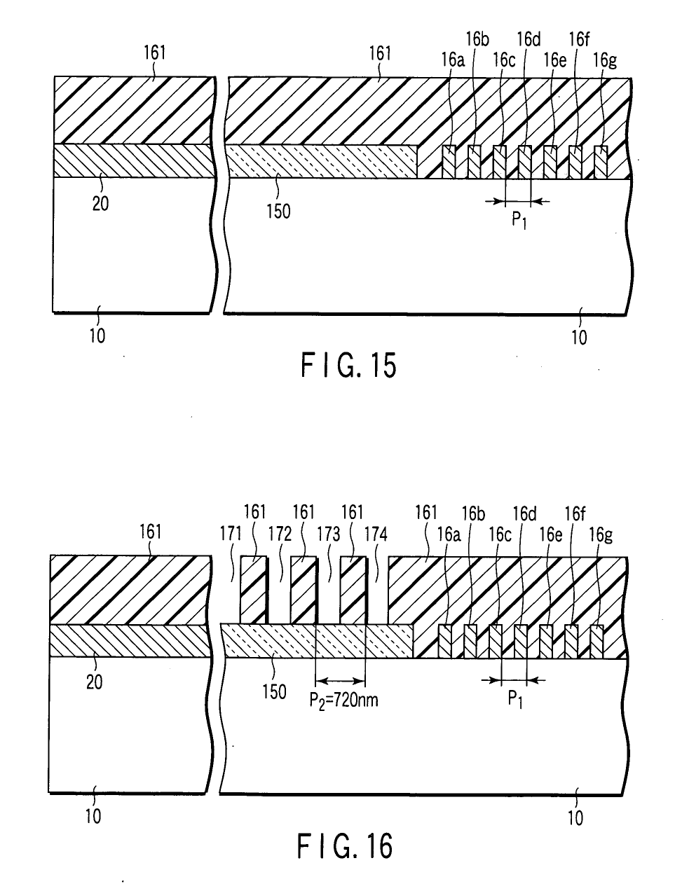

(c) Ashing is carried out to remove the semitransparent film 150 on the second resist film 141 and the second resist film 141, and then, a third resist film 161 is coated over the substrate 10, as shown in FIG. 15. Then, lithography is carried out to form a plurality of apertures 171, 172, 173, and 174 in the third resist film 161 on the semitransparent film 150, as shown in FIG. 16. The apertures 171 to 174 are arranged at a period P₂ more than twice the wavelength λ of light to be irradiated onto a photomask after manufactured.

(d) Anisotropic etching is carried out to remove the part of the semitransparent film 150 that is exposed through the apertures 171 to 174. After that, ashing is carried out to remove the third resist film 161 to form the low density diffraction area 57 having the low-density arranged light reducing portions 17a to 17d made of MoSi or the like shown in FIG. 2 on the substrate 10, thereby completing the structure of the photomask according to the embodiment.

According to the manufacturing method of the photomask described above, both the high-density arranged light reducing portions 16a to 16g made of Cr or the like and low-density arranged light reducing portions 17a to 17d made of MoSi or the like can be formed on the substrate 10.

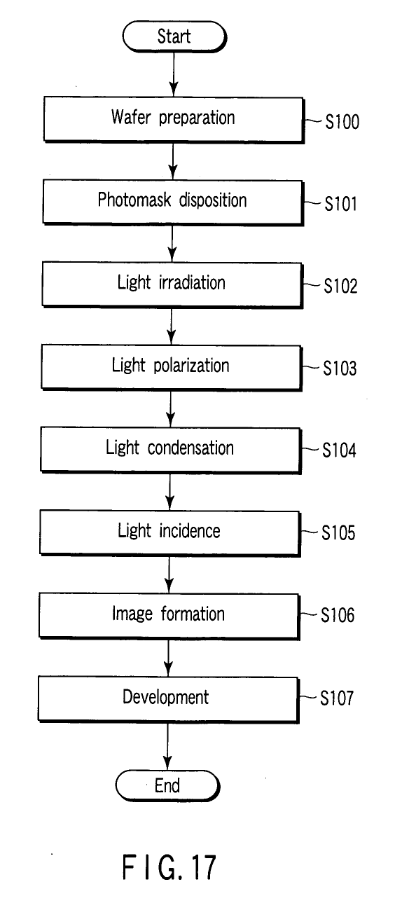

A method of manufacturing a semiconductor device according to the embodiment will be described below, with reference to the flowchart shown in FIG. 17.

(a) In step S100, a wafer made of silicon (Si) or the like is prepared, and a resist film for projection made of a photoresist or the like is coated on the wafer. Then, the wafer on which the resist film for projection has been coated is disposed on the wafer stage 32 of the exposure unit shown in FIG. 5. In step S101, the photomask shown in FIGS. 1 to 4 is disposed on the reticle stage 15. In step S102, irradiation light such as an ArF laser or the like is emitted from the irradiation light source 41 as shown in FIG. 5. In step S103, the irradiation light passing through the polarizer 59 is converted into a polarized light and the shape thereof is set in quadrupole illumination. In step S104, the irradiation light converted into a polarized light is condensed by the light condensation unit 43.

(b) In step S105, the condensed irradiation light obliquely enters the photomask disposed on the reticle stage 15. The irradiation light that has entered the photomask transmits the substrate 10, as shown in FIG. 8, and enters the high density diffraction area 56 and low density diffraction area 57. A part of the irradiation light enters the high density diffraction area 56 at an incident angle θI obtained by the above equation (1). When the irradiation light enters the diffraction areas, the zero-order diffraction light and primary diffraction light are generated both in the high density diffraction area 56 and low density diffraction area 57. In either diffraction areas, the light amount ratio of the primary diffraction light relative to the zero-order diffraction light is near 1.

(c) In step S106, the irradiation light that has transmitted the high density diffraction area 56 and irradiation light that has transmitted the low density diffraction area 57 are guided to the resist film for projection on the wafer disposed on the wafer stage 32, by the projection optical unit 42 shown in FIG. 5. As a result, an image of the pattern on the high density diffraction area 56 and an image of the pattern on the low density diffraction area 57 are projected on the resist film for projection. In step S107, the resist film for projection is developed to form a resist pattern corresponding to the projection image on the wafer. After that, an ion implantation step using the resist pattern as a mask, insulating layer formation step, wiring layer formation step, and the like are repeatedly carried out to complete the structure of the semiconductor device.

According to the manufacturing method of the semiconductor device, a use of the photomask shown in FIGS. 1 to 4 allows both a projection image of the patterns whose arrangement period on the photomask is less than twice the wavelength of irradiation light and a projection image of the patterns whose arrangement period on the photomask is more than twice the wavelength of irradiation light to be focused on the resist film for projection with high accuracy. As a result, it is possible to increase yield of a semiconductor device, even if it has a plurality of wiring patterns with different arrangement periods.

(First Modification)

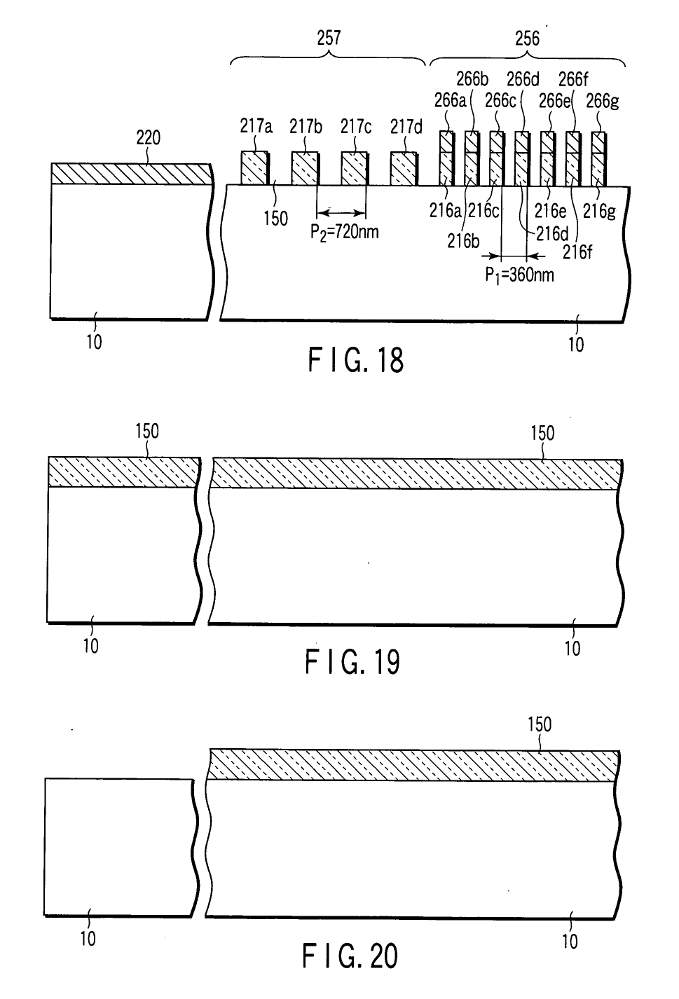

The configuration of the photomask according to the embodiment is not limited to that shown in FIGS. 1 to 4. For example, a high density diffraction area 256 of a photomask according to a first modification shown in FIG. 18 has a plurality of intermediate portions 216a, 216b, 216c, 216d, 216e, 216f, and 216g which are arranged at a period P₁ less than twice the wavelength λ of light to be irradiated onto the substrate 10 and a plurality of high-density arranged light reducing portions 266a, 266b, 266c, 266d, 266e, 266f, and 266g disposed on the intermediate portions 216a, 216b, 216c, 216d, 216e, 216f, and 216g, respectively. A semitransparent transition element compound such as MoSi or the like can be used as a material of the intermediate portions 216a to 216g. Light shielding metal such as Cr or the like can be used as a material of the high-density arranged light reducing portions 266a to 266g. A low density diffraction area 257 has a plurality of low-density arranged light reducing portions 217a, 217b, 217c, and 217d which are arranged at a period P₂ more than twice the wavelength λ of light to be irradiated onto the substrate 10. A semitransparent transition element compound such as MoSi or the like can be used as a material of low-density arranged light reducing portions 217a to 217d. The transmittance of the low-density arranged light reducing portions 217a to 217d is, e.g., 2 to 20%. The low-density arranged light reducing portions 217a to 217d have a film thickness such that a transmitted light of the irradiation light irradiated on the transparent substrate 10, which is directly emitted from the transparent substrate 10, is shifted by 180° in phase from a transmitted light of the irradiation light irradiated on the transparent substrate 10, which is passed through the transparent substrate 10 and the low-density arranged light reducing portions 217a to 217d and emitted from the low-density arranged light reducing portions 217a to 217d. A light shielding film 220 made of Cr or the like is so formed on the substrate 10 as to surround the low density diffraction area 257.

Similarly to the embodiment, in the photomask according to the first modification, the high-density arranged light reducing portions 266a to 266g having an extinction coefficient larger than that of the low-density arranged light reducing portions 217a to 217d of the low density diffraction area 257 are arranged in the high density diffraction area 256 having a period P₁ less than twice the wavelength λ of irradiation light. Therefore, in the high density diffraction area 256, the light amount ratio of the first diffraction light relative to the zero-order diffraction light falls within a range of 0.8 to 1.2, preferably becomes 1. As a result, lithography margin with respect to focus depth or the like increases. Further, in the low density diffraction area 257 having a period P₂ more than twice the wavelength λ of irradiation light, contrast of a projection image is increased by an attenuated phase shift pattern to thereby increase lithography tolerance, as in the case of the photomask shown in FIGS. 1 to 4.

A method of manufacturing the photomask according to the first modification of the embodiment will be described below, with reference to FIGS. 19 to 24.

(a) The substrate 10 made of SiO₂ or the like is prepared. Sputtering or the like is carried out to deposit MoSi or the like on the substrate 10 to form the semitransparent film 150 on the substrate 10, as shown in FIG. 19. The semitransparent film 150 has a film thickness such that a transmitted light of the irradiation light irradiated on the transparent substrate 10, which is directly emitted from the transparent substrate 10, is shifted by 180° in phase from a transmitted light of the irradiation light irradiated on the transparent substrate 10, which is passed through the transparent substrate 10 and the semitransparent film 150 and emitted from the semitransparent film 150. Then, lithography, anisotropic etching, or the like are used to selectively remove a part of the semitransparent film 150, as shown in FIG. 20.

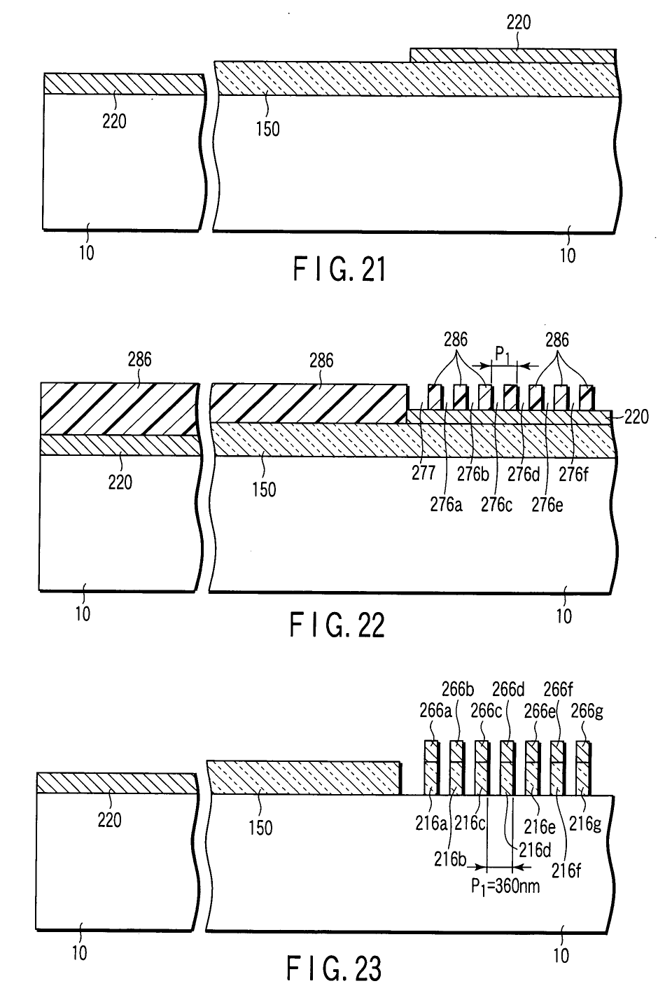

(b) Vacuum deposition or the like is carried out to deposit Cr or the like on the entire surface of the substrate 10 including the surface of the semitransparent film 150, and then lithography, anisotropic etching, or the like are carried out to form the light shielding film 220 on the entire exposed surface of the substrate 10 and a part of the semitransparent film 150 as shown in FIG. 21. Then, a first resist film 286 is spin-coated on the semitransparent film 150 and light shielding film 220. After that, lithography is carried out to form an aperture 277 and a plurality of apertures 276a, 276b, 276c, 276d, 276e, and 276f in the first resist film 286.

(c) Anisotropic etching or the like is carried out to remove the part of the light shielding film 220 and the part of the semitransparent film 150 that are exposed through the apertures 276a to 276f to form the intermediate portions 216a to 216g and high-density arranged light reducing portions 266a to 266g of the high density diffraction area 256, as shown in FIG. 23.

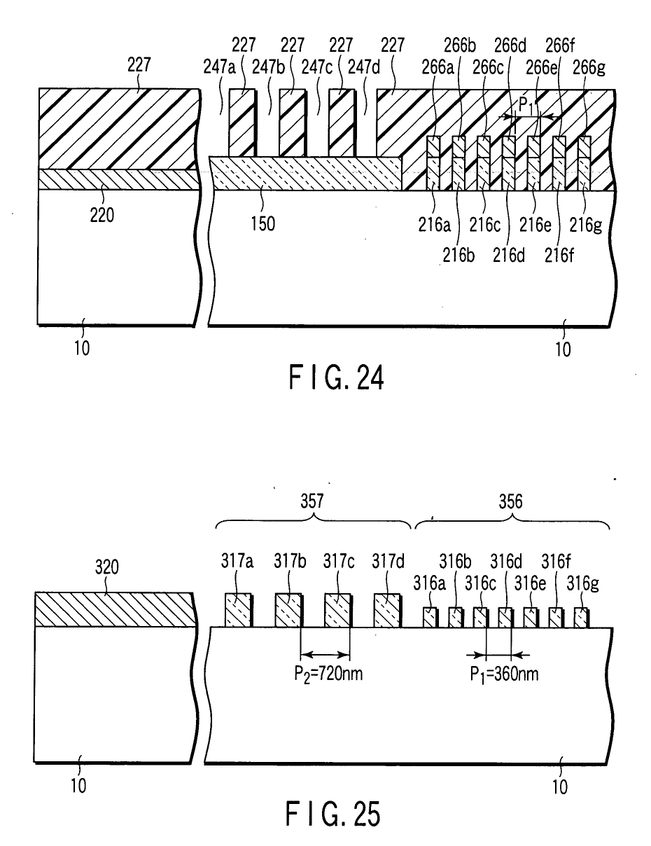

(d) A second resist film 227 is spin-coated on the substrate 10, as shown in FIG. 24. After that, lithography or the like is carried out to form a plurality of apertures 247a, 247b, 247c, and 247d in the second resist film 227 on the semitransparent film 150. After that, the part of the semitransparent film 150 that is exposed through the apertures 247a to 247d is removed to thereby form low-density arranged light reducing portions 217a to 217d of the low density diffraction area 257, as shown in FIG. 18, thus completing the structure of the photomask according to the first modification.

(Second Modification)

As described above, when the period at which the light reducing portions made of MoSi are arranged becomes equal or less than the wavelength λ of irradiation light, the light amount ratio of the primary diffraction light relative to the zero-order diffraction light moves away from 1, resulting in decrease of the contrast of a projection image. Further, when the incident angle θI (equation (1)) of light irradiated onto the photomask becomes large with advancement in fineness of a manufactured semiconductor device, optical characteristics concerning the phase difference occurring in the light reducing portions arranged at a period twice, or equal or less than the wavelength λ of irradiation light can cause the decrease of the contrast of a projection image. That is, even if the phase difference between a light passing through a light transmittable portion and a light passing through a light reducing portion is set to become 180° with respect to a pattern having a larger pitch, actual phase difference is shifted from 180° when the period of the pattern of the light reducing portion falls below twice the wavelength. As a result, unnecessary phase difference occurs between the zero-order diffraction light and primary diffraction light, resulting in decrease of the contrast of a projection image.

In view of the above, the photomask according to a second modification of the embodiment includes, as shown in FIG. 25, the transparent substrate 10 which receives irradiation light, a low density diffraction area 357 which is disposed on the substrate 10 and has a light reducing portion arrangement period P2 more than twice the wavelength of irradiation light, and a high density diffraction area 356 which is disposed on the substrate 10 and has a light reducing portion arrangement period P1 less than twice the wavelength of irradiation light. The phase difference occurred in the high density diffraction area 356 is slightly shifted from the phase difference occurred in the low density diffraction area 357 between a transmitted light of the irradiation light irradiated on the transparent substrate 10, which is directly emitted from the transparent substrate 10 and a transmitted light of the irradiation light irradiated on the transparent substrate 10, which is passed through the transparent substrate 10 and the light reducing portions and emitted from the light reducing portions.

The high density diffraction area 356 has a plurality of high-density arranged light reducing portions 316a, 316b, 316c, 316d, 316e, 316f, and 316g which are arranged at a period P₁ less than twice the wavelength λ of light to be irradiated onto the substrate 10. A semitransparent transition element compound such as MoSi or the like can be used as a material of the high-density arranged light reducing portions 316a to 316g. The transmittance of the high-density arranged light reducing portions 316a to 316g is, e.g., 2 to 20%. The high-density arranged light reducing portions 316a to 316g have a film thickness such that a transmitted light of the irradiation light irradiated on the transparent substrate 10, which is directly emitted from the transparent substrate 10, is shifted by 3° or more from 180°, more preferably, by 10° or more from 180° in phase from a transmitted light of the irradiation light irradiated on the transparent substrate 10, which is passed through the transparent substrate 10 and the high-density arranged light reducing portions 316a to 316g and emitted from the high-density arranged light reducing portions 316a to 316g.

The low density diffraction area 357 has a plurality of low-density arranged light reducing portions 317a, 317b, 317c, and 317d which are arranged at a period P₂ more than twice the wavelength λ of light to be irradiated onto the substrate 10. A semitransparent transition element compound such as MoSi or the like can be used as a material of the low-density arranged light reducing portions 317a to 317d. The transmittance of the low-density arranged light reducing portions 317a to 317d is, e.g., 2 to 20%. The low-density arranged light reducing portions 317a to 317d have a film thickness such that a transmitted light of the irradiation light irradiated on the transparent substrate 10, which is directly emitted from the transparent substrate 10, is shifted by 180° in phase from a transmitted light of the irradiation light irradiated on the transparent substrate 10, which is passed through the transparent substrate 10 and the low-density arranged light reducing portions 317a to 317d and emitted from the low-density arranged light reducing portions 317a to 317d.

As described above, if the film thickness of the light reducing portions is selected such that the phase difference between a transmitted light directly emitted from the transparent substrate 10 after entering the substrate 10 and a transmitted light emitted from the light reducing portions after entering the substrate 10 and passing through the light reducing portions becomes near 180° in the case where the period at which the light reducing portions are arranged is more than twice the wavelength λ of irradiation light, the contrast of a projection image decreases when the period at which the light reducing portions are arranged becomes less than twice the wavelength λ. On the other hand, in the photomask according to the second modification, the film thickness of the high-density arranged light reducing portions 316a to 316g is set such that the phase difference between the transmitted light directly emitted from the transparent substrate 10 after entering the substrate 10 and the transmitted light emitted from the high-density arranged light reducing portions 316a to 316g after entering the substrate 10 and passing through the high-density arranged light reducing portions 316a to 316g is shifted by 3° or more from 180°, more preferably, by 10° or more from 180°. This allows the phase difference between the zero-order diffraction light and primary diffraction light in the high density diffraction area 356 to be approximated to zero. As a result, a projection image of the high density diffraction area 356 whose light reducing portion arrangement period P1 is less than twice the wavelength λ of irradiation light can be formed with high contrast.

Further, in the photomask according to the second modification, the low-density arranged light reducing portions 317a to 317d have a film thickness such that a transmitted light of the irradiation light irradiated on the transparent substrate 10, which is directly emitted from the transparent substrate 10, is shifted by 180° in phase from a transmitted light of the irradiation light irradiated on the transparent substrate 10, which is passed through the transparent substrate 10 and the low-density arranged light reducing portions 317a to 317d and emitted from the low-density arranged light reducing portions 317a to 317d. That is, the film thickness of the high-density arranged light reducing portions 316a to 316g and the film thickness of the low-density arranged light reducing portions 317a to 317d are set such that a first light path length, which is the light path length of the irradiation light passing through the high-density arranged light reducing portions 316a to 316g perpendicularly thereto, and a second light path length, which is the light path length of irradiation light passing through the low-density arranged light reducing portions 317a to 317d perpendicularly thereto, do not correspond to each other.

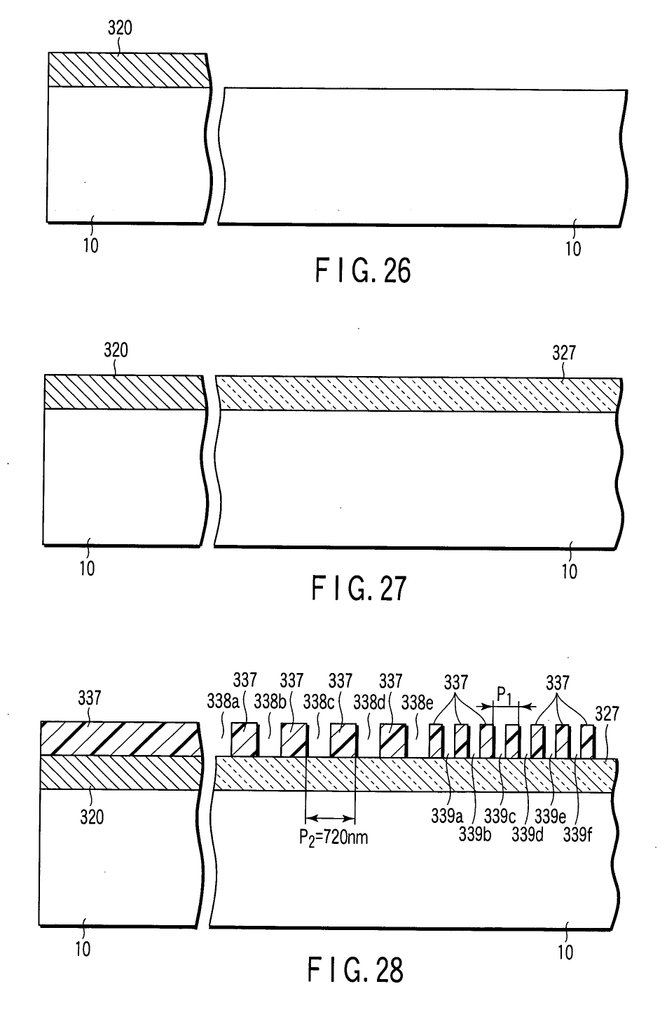

A method of manufacturing the photomask according to the second modification of the embodiment will be described below, with reference to FIGS. 26 to 30.

(a) As shown in FIG. 26, the substrate 10 made of SiO₂ on a part of the surface of which a light shielding film 320 made of Cr or the like has been formed is prepared. Then, lithography, sputtering and the like are carried out to deposit MoSi or the like on the exposed surface of the substrate 10 to form a semitransparent film 327 on the substrate 10, as shown in FIG. 27. The semitransparent film 327 has a film thickness such that a transmitted light of the irradiation light irradiated on the transparent substrate 10, which is directly emitted from the transparent substrate 10, is shifted by 180° in phase from a transmitted light of the irradiation light irradiated on the transparent substrate 10, which is passed through the transparent substrate 10 and the semitransparent film 327 and emitted from the semitransparent film 327.

(b) As shown in FIG. 28, a first resist film 337 is spin-coated on the light shielding film 320 and semitransparent film 327, and lithography or the like is carried out to form a plurality of apertures 338a, 338b, 338c, 338d, and 338e, and a plurality of apertures 339a, 339b, 339c, 339d, 339e, and 339f in the first resist film 337. The apertures 339a to 339f are formed at a period P₁ less than twice the wavelength of light to be irradiated onto a photomask after manufactured. The apertures 338a to 338e are formed at a period P₂ more than twice the wavelength of light to be irradiated onto a photomask after manufactured.

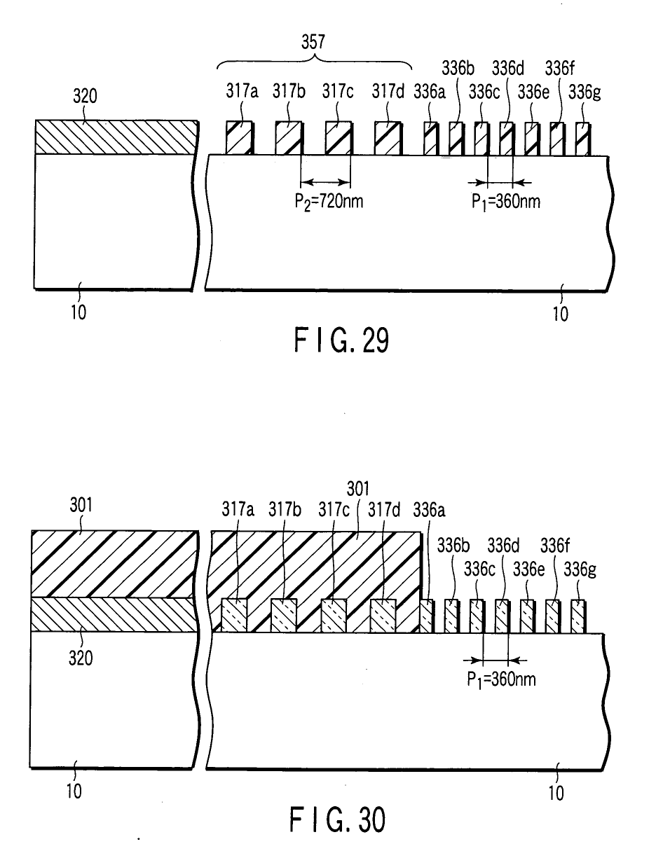

(c) As shown in FIG. 29, the part of the semitransparent film 327 that is exposed through the apertures 338a to 338e and apertures 339a to 339f is removed to form the low-density arranged light reducing portions 317a, 317b, 317c, and 317d of the low density diffraction area 357 and a plurality of shifter intermediates 336a, 336b, 336c, 336d, 336e, 336f, and 336g. The shifter intermediates 336a to 336g are formed at a period P₁ less than twice the wavelength of light to be irradiated onto a photomask after manufactured.

(d) As shown in FIG. 30, a second resist film 301 is spin-coated on the entire surface of the substrate 10. Then, lithography is carried out to selectively remove the second resist film 301 to expose the shifter intermediates 336a to 336g. After that, anisotropic etching or the like is carried out to reduce the film thickness of the shifter intermediates 336a to 336g to form the high-density arranged light reducing portions 316a to 316g of the high density diffraction area 356 shown in FIG. 25, thereby completing the structure of the photomask according to the second modification of the embodiment.

(Another Embodiment)

Although the present invention has been described with reference to the embodiments, it should not be understood that descriptions and drawings constituting a part of this disclosure limit the present invention. For example, a configuration may be adopted in which the extinction coefficient and transmittance of the high-density arranged light reducing portions 16a to 16g and those of the low-density arranged light reducing portions 17a to 17d shown in FIG. 2 are made equal to each other, and the refractive index of the high-density arranged light reducing portions 16a to 16g relative to irradiation light is set such that the phase difference between the zero-order diffraction light and primary diffraction light which occurs in the high density diffraction area 56 becomes zero. By setting the refractive index of the high-density arranged light reducing portions 16a to 16g relative to irradiation light such that the phase difference between the zero-order diffraction light and primary diffraction light in the high density diffraction area 56 becomes zero, it is possible to increase lithography margin with respect to focus depth or the like. The materials of the high-density arranged light reducing portions 16a to 16g and low-density arranged light reducing portions 17a to 17d are not limited to those described in the embodiment. For example, examples of the material of the low-density arranged light reducing portions 17a to 17d further include chromium fluoride (CrF) and transition-silicide compounds such as molybdenum silicide oxide (MoSiO), tungsten silicide oxide (WSiO), zirconium silicide oxide (ZrSiO), molybdenum silicide oxinitride (MoSiON) and silicide oxinitride (SiON). The semitransparent film constituting the low density diffraction area is not limited to the single-layer structure, and may be of a multi-layer structure. For example, a Ta/SiO₂ (tantalum/silicon oxide) film may be used as a multi-layer structure film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A photomask comprising:
a substrate transparent to irradiation light;
a low density diffraction area having a plurality of low-density arranged light reducing portions which are arranged at a low density on the transparent substrate at a period more than twice the wavelength of the irradiation light; and
a high density diffraction area having a plurality of high-density arranged light reducing portions which are arranged at a high density on the transparent substrate at a period less than twice the wavelength of the irradiation light and have different optical characteristics from the low-density arranged light reducing portions.

2. A photomask according to claim 1, wherein the low-density arranged light reducing portions is made of semitransparent transition element.

3. A photomask according to claim 2, wherein the semitransparent transition element is selected from molybdenum silicide (MoSi), chromium fluoride (CrF), molybdenum silicide oxide (MoSiO), tungsten silicide oxide (WSiO), zirconium silicide oxide (ZrSiO), molybdenum silicide oxinitride (MoSiON) and silicide oxinitride (SiON), or is made of tantalum/silicon oxide (Ta/SiO₂).

4. A photomask according to claim 1, wherein the high-density arranged light reducing portions is made of light shielding metal.

5. A photomask according to claim 4, wherein the light shielding metal is chromium (Cr).

6. A photomask according to claim 1, wherein the high-density arranged light reducing portions are arranged on the substrate at a period of 360 nm, in the case where the photomask is irradiated by the irradiation light of an argon fluoride (ArF) laser having a wavelength of 193 nm.

7. A photomask according to claim 1, wherein the low-density arranged light reducing portions of the low density diffraction area are provided in a peripheral circuit region of a semiconductor memory device.

8. A photomask according to claim 1, wherein the high-density arranged light reducing portions of the high density diffraction area are provided in a memory cell region of a semiconductor memory device.

9. A photomask according to claim 1, wherein the low-density arranged light reducing portions have a film thickness such that a transmitted light of the irradiation light irradiated on the transparent substrate, which is directly emitted from the transparent substrate, is shifted by 180° in phase from a transmitted light of the irradiation light irradiated on the transparent substrate, which is passed through the transparent substrate and the low-density arranged light reducing portions and emitted from the low-density arranged light reducing portions.

10. A photomask according to claim 1, wherein an extinction coefficient of the high-density arranged light reducing portions relative to the irradiation light is larger than an extinction coefficient of the low-density arranged light reducing portions relative to the irradiation light.

11. A photomask according to claim 10, wherein materials of the high-density arranged light reducing portions and low-density arranged light reducing portions are selected so that the extinction coefficient of the high-density arranged light reducing portions is larger than the extinction coefficient of the low-density arranged light reducing portions.

12. A photomask according to claim 1, wherein the high density diffraction area comprises a plurality of intermediate portions formed on the substrate at the period less than twice the wavelength of the irradiation light and the plurality of high-density arranged light reducing portions formed on the intermediate portions.

13. A photomask according to claim 1, wherein the high-density arranged light reducing portions have a film thickness such that a transmitted light of the irradiation light irradiated on the transparent substrate, which is directly emitted from the transparent substrate, is shifted in phase from a transmitted light of the irradiation light irradiated on the transparent substrate, which is passed through the transparent substrate and the high-density arranged light reducing portions and emitted from the high-density arranged light reducing portions.

14. A photomask according to claim 1, wherein a refractive index of the high-density arranged light reducing portions relative to the irradiation light is set such that a phase of a zero-order diffraction light and a phase of a primary diffraction light which occurs in the high density diffraction area are equal to each other.

15. A photomask according to claim 1, wherein a first light path length of the irradiation light that transmits perpendicularly the high-density arranged light reducing portions and a second light path length of the irradiation light that transmits perpendicularly the low-density arranged light reducing portions are different from each other.

16. A method of manufacturing a semiconductor device, comprising:
emitting irradiation light;
condensing the emitted irradiation light;
entering the condensed irradiation light obliquely to a low density diffraction area having a plurality of low-density arranged light reducing portions which are arranged at a period more than twice a wavelength of the irradiation light and a high density diffraction area having a plurality of high-density arranged light reducing portions which are arranged at a period less than twice the wavelength and having different optical characteristics from the low-density arranged light reducing portions;
forming projection images of the high density diffraction area and low density diffraction area on a resist film for projection coated on a wafer by the oblique entering of the irradiation light; and
developing the resist film for projection to form a resist pattern corresponding to the projection images on the wafer.

17. A method of manufacturing a semiconductor device according to claim 16, wherein the low-density arranged light reducing portions is made of semitransparent transition element.

18. A method of manufacturing a semiconductor device according to claim 17, wherein the semitransparent transition element is selected from molybdenum silicide (MoSi), chromium fluoride (CrF), molybdenum silicide oxide (MoSiO), tungsten silicide oxide (WSiO), zirconium silicide oxide (ZrSiO), molybdenum silicide oxinitride (MoSiON) and silicide oxinitride (SiON), or is made of tantalum/silicon oxide (Ta/SiO₂).

19. A method of manufacturing a semiconductor device according to claim 16, wherein the high-density arranged light reducing portions is made of light shielding metal.

20. A method of manufacturing a semiconductor device according to claim 19, wherein the light shielding metal is chromium (Cr).
